(19) United States
(12) Patent Application Publication
(10) Pub. No.: US 2008/0290523 A1
(43) Pub. Date: Nov. 27, 2008

(54) Semiconductor device including barrier metal and coating film and method for manufacturing same

(75) Inventor: Chieri Teramoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/081,930

(22) Filed: Apr. 23, 2008

(30) Foreign Application Priority Data
May 23, 2007 (JP) 2007-136460

(51) Int. Cl. H01L 23/52; H01L 21/4763

(52) U.S. Cl. 257/763; 438/625; 257/E21.506

(57) ABSTRACT

A semiconductor device includes an interconnection layer provided on a substrate, a first insulating film provided on the substrate, and on the interconnection layer so as to coat the interconnection layer, the first insulating film includes a silicon oxide film, a second insulating film provided on the first insulating film, the second insulating film includes either a silicon oxynitride film or a silicon nitride film, and an insulative coating film provided on the second insulating film.

### BACKGROUND OF THE INVENTION

1. Field of the Invention

The present invention relates to a semiconductor device having a structure wherein an interconnection layer over a substrate is coated with a protective film, and a method for manufacturing the same.

2. Description of Related Art

There has been known a semiconductor device having an interconnection layer provided over a principal surface of a substrate, the principal surface side portion of the substrate having insulation properties, and a protective film provided for protection of the interconnection layer.

FIG. 1 is a sectional view broadly showing a constitution of a common semiconductor device. The semiconductor device shown in FIG. 1 includes a substrate 11 provided with an insulating film 12 on the top surface thereof, and an interconnection layer 13 in the topmost layer, provided over the substrate 11 through the intermediary of the insulating film 12. The interconnection layer 13 includes a barrier metal 13-1 in the bottom layer, an interconnection metal 13-2, and a barrier metal 13-3, stacked in that order. The interconnection layer 13 is coated with a protective film 14. The protective film 14 is formed in the topmost layer of the semiconductor device. For the protective film, use is made of an insulating film excellent in moisture resistance in order to protect internal elements from a usage environment. The insulating film includes, for example, a silicon oxide film, and a CVD film such as a silicon oxynitride film, and so forth. There may be cases where the protective film is of a layered structure. In FIG. 1, there is shown a case where the protective film 14 is formed of a silicon oxide (SiO₂) film (14-1) disposed in a lower layer, and a silicon oxynitride (SiON) (14-2) film.

If a protective film is formed by use of a CVD method and so forth, then there are cases where pits and projections, caused by a thickness of an interconnection layer, are formed on the surface of the protective film. If the pits and projections are present on the surface of the protective film, then there is a possibility that problems such as variation in height of bumps, and so forth, occur when the bumps are formed in a back-end step of processing.

Accordingly, there has been known a technology whereby an SOG (Spin on Glass) film is used to serve as the protective film for the interconnection layer. It is possible to render the surface of the protective film substantially flat by forming the protective film with the use of a coating method. In the case of employing the coating method, the SOG film is formed after coating the interconnection layer with a SiN film, a PSG (phosphorus silicate glass) film, and so forth in order to protect the interconnection layer side of the SOG film from moisture and so forth, evolved at the time of coating.

Patent Document 1 has disclosed a semiconductor device using the SOG film. FIG. 2 is a sectional view of the semiconductor device disclosed in Patent Document 1. As shown in FIG. 2, the semiconductor device disclosed in Patent Document 1 is provided with a silicon substrate 101, an interlayer dielectric 102 formed on the top of the silicon substrate 101, aluminum interconnections 103 provided on the top of interlayer dielectric 102, a CVD-PSG film 104 coating the aluminum interconnections, a first plasma nitriding silicon film 105 provided on the top of the CVD-PSG film 104, an SOG film 106 provided so as to fill up difference in level, and a second plasma nitriding silicon film 107 provided in a layer on the top of the SOG film 106.

Further, as shown in FIG. 3, Patent Document 2 has disclosed a passivation structure wherein an interconnection layer 112 formed on the top of a substrate 111 is coated with an SiN layer 113, and a spin-on glass material 114, and a silicon oxynitride film 115 are provided in that order on the top of the SiN layer 113.

[Patent Document 1] Japanese Patent Laid Open Application No. Hei 05(1993)-055199

### [Patent Document 2] Japanese Patent Laid Open Application No. 2004-111707

Progress has lately been made in miniaturization of the interconnection layer. As spacing between interconnections becomes smaller, conformability at the time of coating the interconnection layer will become important. FIG. 4 is a schematic illustration for illustrating a state when an interconnection layer that is narrow in interconnection interval is coated with films poor in conformability. In FIG. 4, film constitution is the same as that shown in FIG. 1, omitting therefore description thereof. As shown in FIG. 4, if films poor in conformability are used, then there is a possibility that spacing (void) 15 with a closed upper part occurs between the interconnections in the films. There can be cases where air remaining in the spacing 15 will induce explosion, for example, in the case where treatment is carried out in a vacuum atmosphere in a back-end step of processing, so that the films themselves are destroyed. The narrower the interconnection interval, and the greater the thickness of the interconnection, the more prone to occur the spacing 15 will be. As further progress is made in the miniaturization of the interconnection, further increase in the thickness of the interconnection is required in order to enhance reliability. However, it has since become difficult to increase the thickness of the interconnection in fear of occurrence of the spacing 15, at the time of coating with the protective film. The PSG film adopted in Patent Document 1 is not good in conformability. Accordingly, it is deemed that use of the PSG film will interfere with the miniaturization of the interconnection as described with reference to FIG. 4.

Further, if the interconnection layer is coated with the SiN layer, as in the case of Patent Document 2, then the interconnection layer may undergo degradation due to SM (stress migration in storage at constant-temperature), and so forth because membrane stress of the SiN layer is large. FIG. 5 shows a semiconductor device wherein an interconnection layer 123 is formed on the top of an insulating film 122 formed on the top of a substrate 121, and an SiN film 124, an SOG film 125, and an SiN film 126 are formed in that order on the top of the interconnection layer 123. The interconnection layer 123 includes a metal interconnection 123-2, and barrier metals 123-1, 123-3, formed on the bottom and the top of the metal interconnection 123-2, respectively. If such a constitution is adopted, then this will cause a degradation part 127 to be formed in the interconnection layer 123.

Furthermore, owing to requirements for higher working speed of the semiconductor device, low permittivity characteristics are lately required of the protective film as well. Since the SiN film is high in permittivity, it is difficult to satisfy permittivity characteristics as required if the SiN film makes up a major portion of the interconnection interval.

Under the circumstance, the inventor has focused attention on a silicon oxide film as a film for use in coating of the interconnection layer. The silicon oxide film is excellent in conformability, and the membrane stress thereof is small. Then, the inventor has studied planarization of the surface by the coating method after coating the interconnection layer with the silicon oxide film. However, it has been found out that the following problem occurs depending on the type of a silicon oxide film in use.

If the silicon oxide film is in direct contact with the interconnection layer, and is put to use in an environment of high temperature and high humidity at high voltage, then there can be cases where the interconnection layer undergoes electrolytic etching. Particularly, in the case where the interconnection layer is of a layered structure, and a barrier metal is present on interconnections, the barrier metal is prone to be subjected to electrolytic etching by the agency of the silicon oxide film. For the barrier metal, use is generally made of a film containing Ti (for example, a TiN film). In the case of using the TiN film as the barrier metal, the TiN film undergoes transformation into a TiO₂ {or Ti (OH)₄} film white in color. Because such a reaction is accompanied by expansion in volume, which will induce destruction of the protective film, thereby creating a cause for impairing long-term reliability of the semiconductor device. If a planarization film is further formed on the top of the silicon oxide film by use of the coating method, this will further promote the electrolytic etching of the interconnection layer, caused by the silicon oxide film. After having reviewed an optimum structure of the protective film in order to cope with such problems as described, the inventor, et al. have finally succeeded in development of the present invention.

### SUMMARY OF THE INVENTION

A semiconductor device according to an exemplary aspect of the present invention includes an interconnection layer provided over a substrate, a first insulating film provided over the substrate, and on the interconnection layer so as to coat the interconnection layer, a second insulating film provided on the first insulating film, and a coating film having insulation properties, provided on the second insulating film. The first insulating film is a silicon oxide film and the second insulating film is a silicon oxynitride film or a silicon nitride film.

A method for manufacturing a semiconductor device according to an exemplary aspect of the present invention, the method includes forming an interconnection layer over a substrate, forming a first insulating film over the substrate, and on the interconnection layer to coat the interconnection layer, forming a second insulating film on the first insulating film, and forming a coating film on the second insulating film by a coating method. The first insulating film is a silicon oxide film and the second insulating film is a silicon oxynitride film, or a silicon nitride film.

With such a constitution as described above, the second insulating film prevents electrolytic etching of the interconnection layer, due to the effect of the coating film. Further, the first insulating film, and the second insulating film are excellent in conformability, and are small in film thickness, so that it is possible to prevent occurrence of the spacing (voids) with the closed upper part between the interconnections in the films. Still further, the silicon oxide film used as the first insulating film is small in membrane stress, and it is possible to prevent degradation of the interconnection layer due to SM, etc. Yet further, the coating film is excellent in embedding properties without causing occurrence of spacing even between the interconnections, and is also excellent in surface evenness.

The present invention provides a semiconductor device capable of preventing the electrolytic etching of the interconnection layer when the planarization film is formed by the coating method, and a method for manufacturing the same.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 illustrates a sectional view showing a constitution of a common semiconductor device;

FIG. 2 illustrates a sectional view showing a structure of a semiconductor device disclosed in Patent Document 1;

FIG. 3 illustrates a sectional view showing a structure of a semiconductor device disclosed in Patent Document 2;

FIG. 4 illustrates a schematic illustration for illustrating spacing occurring between interconnection layers;

FIG. 5 illustrates a schematic illustration for illustrating degradation occurring to the interconnection layer, due to stress migration;

FIG. 6 illustrates a sectional view broadly showing a constitution of a semiconductor device according to an exemplary embodiment of the invention;

FIG. 7 illustrates a flow chart showing a method for manufacturing the semiconductor device according to the embodiment of the invention;

FIGS. 8A to 8D illustrate each thereof is a sectional view showing each of steps of processing for the method for manufacturing the semiconductor device according to the exemplary embodiment of the invention; and

FIGS. 9A and 9B are schematic views for illustrating electrolytic etching of the interconnection layer.

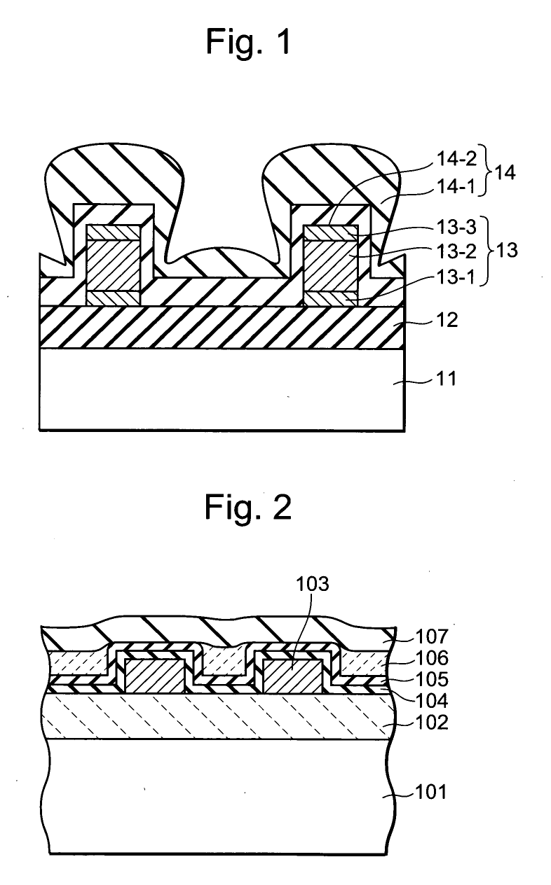

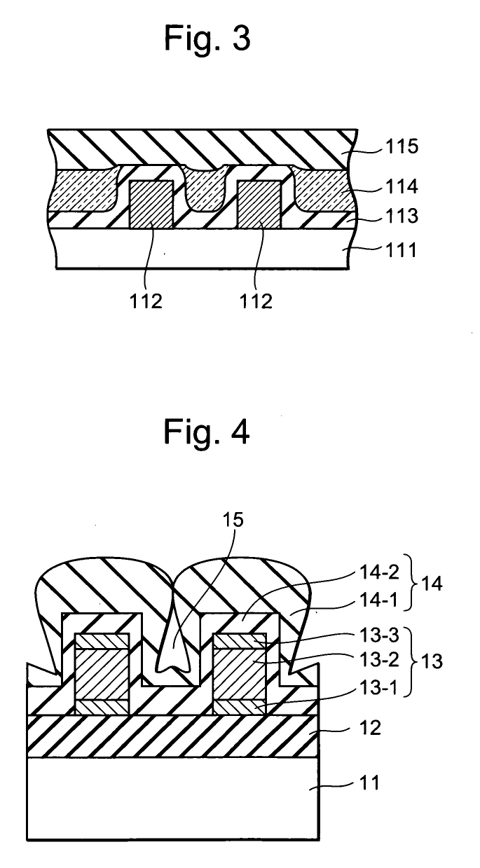

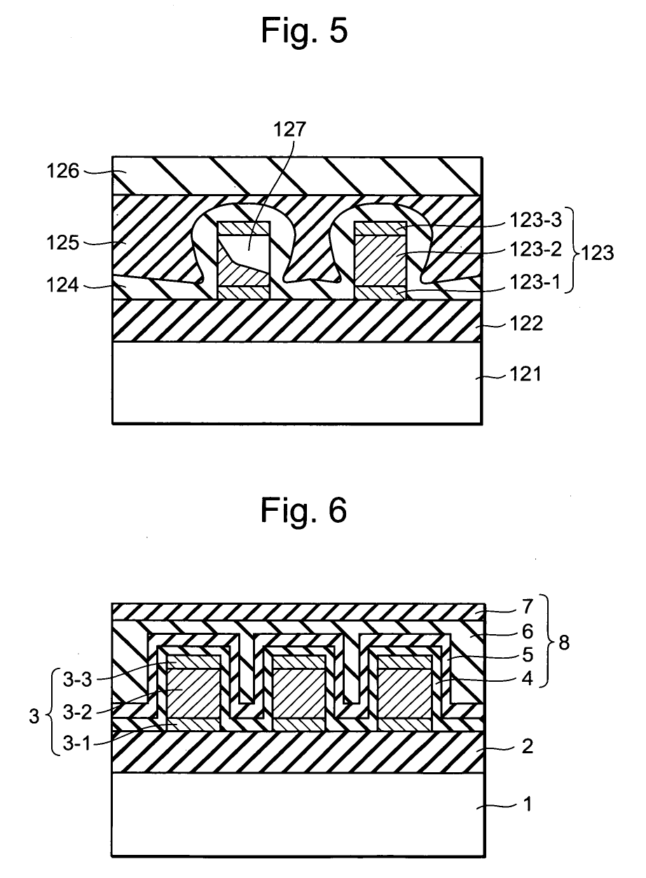

### DETAILED DESCRIPTION OF THE EXEMPLARY EMBODIMENTS

FIG. 6 is a sectional view broadly showing a constitution of a semiconductor device according to an exemplary embodiment of the invention.

The semiconductor device is provided with a silicon substrate 1, an insulating film 2, an interconnection layer 3, a first insulating film 4, a second insulating film 5, a coating film 6, and a third insulating film 7.

The insulating film 2 is provided on the top of a principal surface of the silicon substrate 1. The insulating film 2 is, for example, a silicon oxide film. Desired circuits are formed of semiconductor elements, such as transistors, and so forth, contacts, via holes, and so forth, (not shown), to be disposed on the silicon substrate 1, and the insulating film 2, respectively. The interconnection layer 3 is formed on the top of the insulating film 2. A single layer or a plurality of layers of interconnection layers (not shown) other than the interconnection layer 3 may be formed in the insulating film 2, in which case, the interconnection layer 3 corresponds to an interconnection layer in the uppermost layer of multilevel interconnection layers. In the case of the interconnection layer 3 being the interconnection layer in the uppermost layer of the multilevel interconnection layers, the interconnection layer 3 is in connection with an interconnection layer directly thereunder through predetermined via holes provided in the insulating film 2

The interconnection layer 3 is in the form of a layered structure comprising an interconnection metal 3-2, and barrier metals 3-1, 3-3, formed on the bottom and the top of the interconnection metal 3-2, respectively, in order to prevent diffusion of constituent elements thereof. For the barrier metals 3-1, 3-3, use is made of a layer containing Ti. With the present embodiment of the invention, it is assumed that the interconnection 3-2 is an Al layer, and the barrier metals 3-1, 3-3 each are a TiN layer. Further, it is assumed that the interconnection layers 3 adjacent to each other include an interconnection gap having an aspect ratio not less than 1.4. Herein, the interconnection gap refers to an interval between the interconnection layers 3 adjacent to each other in the horizontal direction, and the aspect ratio of the gap is expressed by b/a where an interconnection interval (space) is “a”, and a height of the interconnection layer 3 is “b”.

The first insulating film 4 is provided on the top of the interconnection layer 3 in such a way as to coat the interconnection layer 3, and over the insulating film 2 formed on the top of the silicon substrate 1. For the first insulating film 4, use is made of a silicon oxide film. Further, the first insulating film 4 is assumed to be 50 mm in thickness. The first insulating film 4 may be 10 mm in thickness, and in the case where the interconnection layers 3 adjacent to each other includes the interconnection gap having the aspect ratio not less than 1.4, the first insulating film 4 is preferably not more than 50 nm in thickness from the viewpoint of conformability, and membrane stress.

The second insulating film 5 is provided in such a way as to coat the first insulating film 4. The second insulating film 5 is provided in order to prevent the first insulating film 4 from being polarized by a planarization film 6 to be described later, thereby corroding the interconnection layer 3. For the second insulating film 5, use can be made of a silicon oxynitride film, or a silicon nitride film. Use of the silicon nitride film is more preferable from the viewpoint of conformability. With the present embodiment of the invention, it is assumed that the silicon nitride film is used. Further, the second insulating film 5 is assumed to be 100 nm in thickness. The second insulating film 5 may be 10 nm in thickness, and in the case where the interconnection layers 3 adjacent to each other includes the gap between the interconnections, having the aspect ratio not less than 1.4, the second insulating film 4 is preferably not more than 100 nm in thickness from the viewpoint of conformability, and membrane stress.

The coating film 6 is provided so as to fill up respective gaps due to pits and projections formed on the surface of the second insulating film 5, thereby rendering the surface effectively flat. That is, the coating film 6 is a planarization film 6. The coating film 6 is formed by the coating method. With the present exemplary embodiment of the invention, it is assumed that for the coating film 6, use is made of an HSQ (hydrogen silsesquioxane) film. Since the HSQ film has low permittivity, and is capable of increasing the working speed of a semiconductor device, the HSQ film is preferably used. Further, the HSQ film is excellent in fluidity, and can be sufficiently embedded even in the interconnection gap having the aspect ratio not less than 1.4, so that the HSQ film can be embedded even in the interconnection gap having the aspect ratio not more than, for example, 1.8. Further, the HSQ film is preferably used because the same can render the surface thereof effectively flat, and also from the viewpoint of effecting planarization of the pits and projections on the surface of the second insulating film 5, caused by the interconnection layer 3.

The third insulating film 7 is provided in order to protect the interconnection layer 3 from outside moisture, and so forth, and, for example, a silicon oxynitride film is suitably used for the third insulating film 7. The third insulating film 7 may be a silicon nitride film.

An insulating film layer 8 according to the invention, including the first insulating film 4, the second insulating film 5, the coating film 6, and the third insulating film 7, is most suitably used as a protective film in the topmost layer of the semiconductor device, formed over the interconnection layer 3 as the interconnection layer in the topmost layer, however, the invention is not limited thereto, and the insulating film layer 8 may be used as an interlayer dielectric layer. In the case of using the insulating film layer 8 as the interlayer dielectric layer, another interconnection layer is further formed in an upper layer of the third insulating film 7.

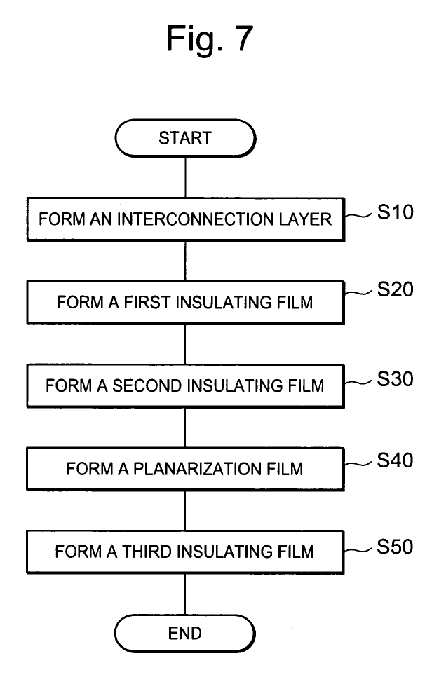

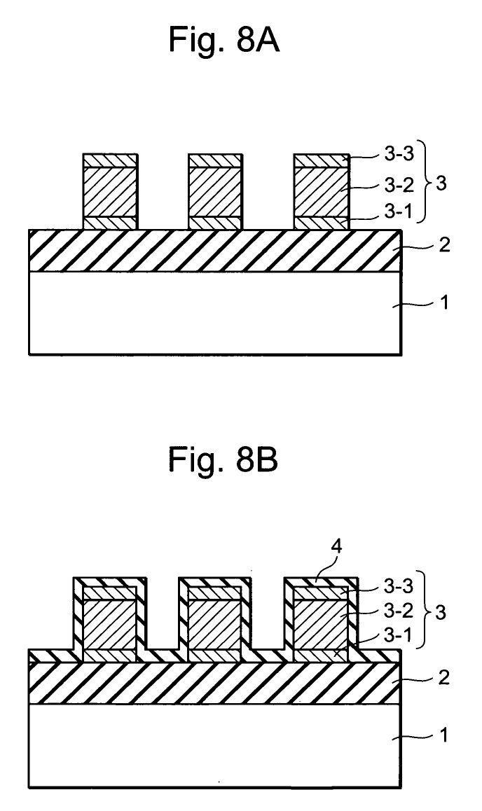

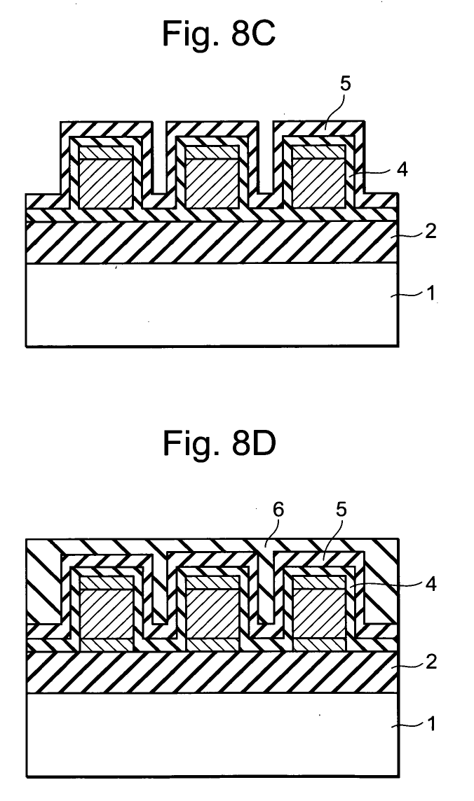

FIG. 7 is a flow chart showing an exemplary method for manufacturing a semiconductor device, according to the present embodiment. FIGS. 8A to 8D each are a sectional view showing each of steps of processing for the method for manufacturing the semiconductor device.

### Step S10: Formation of the Interconnection Layer

As shown in FIG. 8A, the silicon substrate 1 is prepared, and the interconnection layer 3 is formed over the silicon substrate 1 through the intermediary of the insulating film 2.

### Step S20: Formation of the First Insulating Film

As shown in FIG. 8B, the first insulating film 4 is subsequently formed in such a way as to coat the interconnection layer 3. More specifically, a silicon oxide film to serve as the first insulating film 4 is deposited by a plasma CVD method. The first insulating film 4 is formed to a thickness on the order of 50 nm.

### Step S30: Formation of the Second Insulating Film

As shown in FIG. 8C, the second insulating film 5 is subsequently formed in such a way as to coat the first insulating film 4. More specifically, a silicon oxynitride film to serve as the second insulating film 5 is deposited by the plasma CVD method. The second insulating film 5 is formed to a thickness on the order of 100 nm.

Since the first insulating film, and second insulating film each are sufficiently small in thickness as compared with the interval between the interconnection layers 3 adjacent to each other, the gap between the interconnection layers 3 adjacent to each other will not be filled up with the first insulating film, and the second insulating film.

### Step S40: Formation of the HSQ Film

As shown in FIG. 8D, a solution for forming the coating film, containing constituents of the coating film, is applied to the top of the second insulating film 5. After the solution is applied, a solvent of the solution as applied is removed by heat treatment in an N₂ atmosphere, UV irradiation treatment, and so forth. By so doing, the coating film 6 is formed. Then, difference in level on the surface of the second insulating film 5, caused by presence of the interconnection layer 3, is filled up, thereby causing the surface of the substrate to become flat. With the present embodiment of the invention, the HSQ film is used as the coating film 6.

### Step S50: Formation of the Third Insulating Film

Further, the third insulating film 7 is formed on the top of the coating film 6, whereupon the semiconductor device as shown in FIG. 6 can be obtained. More specifically, a silicon oxynitride film is caused to grow to a thickness on the order of 200 to 300 nm by use the plasma CVD method. The silicon oxynitride film is high in moisture resistance, and is effective for protecting the interconnection layer 3 from moisture.

The semiconductor device according to the present embodiment is manufactured by processing according to the steps S10 to S50.

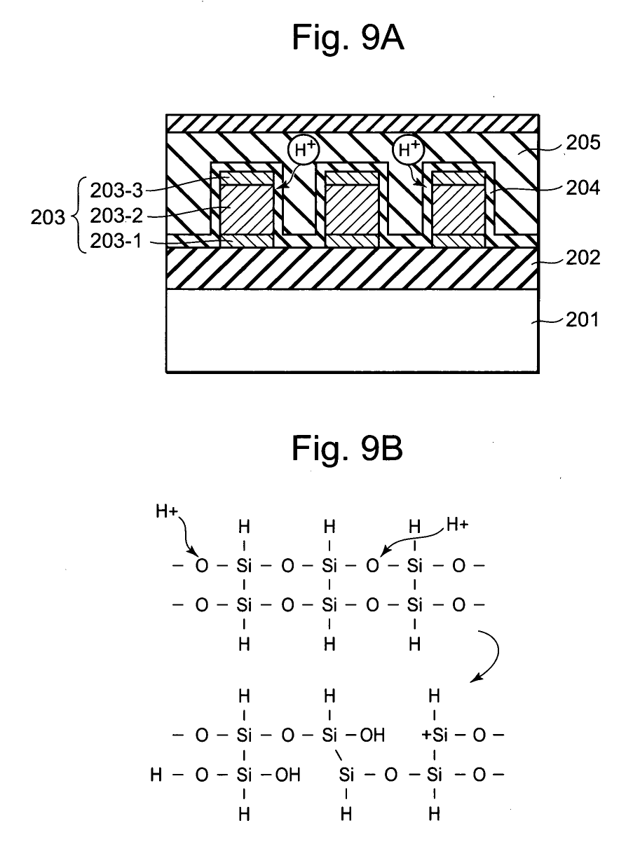

Subsequently, behavior of the present embodiment is described. First, a mechanism whereby the interconnection layer 3 undergoes electrolytic etching is described with reference to FIGS. 9A, and 9B. FIG. 9A is a sectional view of a semiconductor device, showing a constitution wherein an interconnection layer 203 formed on the top of an insulating film 202 on the top of a silicon substrate 201 is directly coated with a silicon oxide film 204, and an HSQ film 205 serving as a planarization film is formed directly on the top of the silicon oxide film 204, the figure being shown for the purpose of comparison with the present embodiment. The interconnection layer 203 includes an interconnection metal 203-2, and barrier metals 203-1, 203-3, formed on the bottom and the top of the metal interconnection 203-2, respectively. Further, a silicon oxynitride film 206 is formed on the top of the HSQ film 205.

As shown in FIG. 9A, if the semiconductor device is placed in a high-temperature high-humidity atmosphere, then a reaction H₂O→H⁺+OH⁻ will proceed in the HSQ film 205, thereby generating H⁺. H⁺ in the HSQ film 205 will permeate the silicon oxide film.

As shown in FIG. 9B, H⁺ that has permeated the silicon oxide film 204 will split a bond of “—O—Si—O—”, thereby generating hydroxyl group (—OH) and Si⁺. As a result, polarization occurs in the silicon oxide film 204. If a high voltage is applied to the interconnection layer 203 in that state, then this will cause the hydroxyl group to be attracted toward the interconnection layer 203. The hydroxyl group as attracted acts as an oxidizing agent at the interconnection layer 203, and a corrosion reaction proceeds therein. Assuming that TiN is used for the barrier metal 203-3 of the interconnection layer 203, TiN is oxidized, whereupon oxides such as Ti(OH)ₓ, or TiOₓ, and so forth will be generated. Since a reaction for generating Ti(OH)ₓ, and TiOₓ is an expansion reaction, passivation films in upper layers (in this case, the silicon oxide film 204, and so forth) are destroyed at the time of generation of the oxides, thereby impairing long-term reliability of the semiconductor device.

In contrast, with the present embodiment, the silicon oxynitride film excellent in moisture resistance, serving as the second insulating film 5, is disposed between the first insulating film 4 that is the silicon oxide film, and the coating film 6 that is the planarization film, as shown in FIG. 6, so that it is possible to prevent permeation of an oxidizing agent (H⁺) from the coating film 6 into the first insulating film 4. Thus, no polarization occurs in the first insulating film 4, thereby checking the corrosion reaction of the interconnection layer 3.

Further, since the silicon oxide film small in membrane stress is used as the first insulating film 4 for coating the interconnection layer 3, it is possible to prevent degradation of the interconnection layer 3, due to SM.

Still further, since a thin film (the first insulating film: 50 nm, the second insulating film: 100 nm) is used as the first insulating film, and the second insulating film, respectively, it is possible to enhance coverable properties of the interconnection layer 3. By so doing, occurrence of the gap between the interconnections can be prevented. That is, it is possible to prevent destruction of the protective film, due to air present in spacing undergoing explosion during vacuum treatment and so forth, carried out in the back-end step of the processing.

Yet further, use of the HSQ film as the coating film 6 that is the planarization film will enable capacitance between the interconnections in the interconnection layer 3 to be reduced, which is advantageous from the viewpoint of interconnection delay.

However, the invention under the present application is not limited to the exemplary embodiment described as above.

The use of HSQ for the coating film is shown by way of example; however, the invention is not limited thereto. Use may be made of MHSQ (Methyl Hydrogen Silsesquioxane) or MSQ (Methyl Silsesquioxane) for the coating film provided that the same is a film formed by the coating method. If MHSQ or MSQ is formed by the coating method, then the MHSQ film, or the MSQ film can be embedded even in the interconnection gap having the aspect ratio not more than 1.8, and the film will be excellent in surface evenness. Further, with the use of MHSQ, and MSQ, permittivity can be rendered lower than that in the case of using HSQ. Further, SOG excellent in surface evenness and embedding properties may be used for the coating film although the effect of low permittivity is not obtained.

Furthermore, a single-layer film of TiN is shown as the barrier metal by way of example, however, a film composed of Ti in a lower layer, and TiN, stacked in that order, may be used instead. Furthermore, the interconnection metal may contain Si, or Cu provided the same is a metal containing Al as the main constituent.

Further, it is noted that, Applicant's intent is to encompass equivalents of all claim elements, even if amended later during prosecution.

What is claimed is:

1. A semiconductor device comprising:
an interconnection layer provided on a substrate;
a first insulating film provided on the substrate, and on the interconnection layer so as to coat the interconnection layer, said first insulating film comprising a silicon oxide film;
a second insulating film provided on the first insulating film, the second insulating film comprising either a silicon oxynitride film or a silicon nitride film; and
an insulative coating film provided on the second insulating film.

2. The semiconductor device according to claim 1, wherein the interconnection layer includes:
an interconnection metal; and
a barrier metal layer disposed between the interconnection metal, and the first insulating film.

3. The semiconductor device according to claim 2, wherein the barrier metal layer comprises a film containing titanium.

4. The semiconductor device according to claim 1, further comprising:
an interconnection gap formed as an interval between interconnection layers adjacent to each other,
wherein the interconnection gap has an aspect ratio as expressed by b/a, of not less than 1.4, provided that the interval between the interconnection layers adjacent to each other is a, and a height of the interconnection layer is b.

5. The semiconductor device according to claim 4, wherein the first insulating film has a thickness in a range of 10 to 50 nm.

6. The semiconductor device according to claim 4, wherein the second insulating film has a thickness in a range of 10 to 100 nm.

7. The semiconductor device according to claim 1, wherein the insulative coating film comprises an HSQ (hydrogen silsesquioxane) film.

8. The semiconductor device according to claim 1, further comprising:
a third insulating film provided on the coating film.

9. The semiconductor device according to claim 8, wherein the third insulating film comprises either a silicon oxynitride film or a silicon nitride film.

10. The semiconductor device according to claim 4, wherein the interconnection gap having the aspect ratio of not more than 1.8 is effectively filled up with the coating film.

11. A method of manufacturing a semiconductor device, comprising:
forming an interconnection layer over a substrate;
forming a first insulating film on the substrate, and on the interconnection layer to coat the interconnection layer, the first insulating film comprising a silicon oxide film;
forming a second insulating film on the first insulating film, the second insulating film comprising either a silicon oxynitride film or a silicon nitride film; and
forming a coating film on the second insulating film.

12. The method according to claim 11, wherein the forming of the interconnection layer includes:
forming an interconnection metal; and
forming a barrier metal layer.

13. The method according to claim 12, wherein the barrier metal layer comprises a film containing titanium.

14. The method according to claim 11, wherein in the forming of the interconnection layer, an interconnection gap as an interval between interconnection layers adjacent to each other, such that the interconnection gap has an aspect ratio as expressed by b/a, of not less than 1.4, provided that the interval between the interconnection layers adjacent to each other is a, and a height of the interconnection layer is b.

15. The method according to claim 14, wherein the first insulating film has a thickness in a range of 10 to 50 nm.

16. The method according to claim 14, wherein the second insulating film has a thickness in a range of 10 to 100 nm.

17. The method according to claim 11, wherein the coating film is an HSQ (hydrogen silsesquioxane) film.

18. The method according to claim 11, further comprising:
forming a third insulating film on the coating film.

19. The method according to claim 18, wherein the third insulating film comprises either a silicon oxynitride film, or a silicon nitride film.

20. The method according to claim 14, wherein in the forming of the coating film by the coating method, the coating film is formed so as to effectively fill up the interconnection gap having the aspect ratio of not more than 1.8.

21. A semiconductor device, comprising:
a plurality of interconnection layers formed on a substrate, said interconnection layers being arranged to have an interval between one another, an interconnection layer of said plurality of interconnection layers including a metal wiring layer and a barrier metal provided to said metal wiring layer, said barrier metal having potential to react with a hydroxyl group;
a first insulating film formed on said substrate, side and top surfaces of said interconnection layers, to form first concaves provided between the respective adjacent interconnection layers, said first insulating film having potential to produce said hydroxyl group with a reaction relating to H⁺;
a second insulating film formed on said first insulating film to form second concaves provided between the respective adjacent interconnection layers, to prevent said H⁺ from approaching said first insulating film; and
a coating film formed on said second insulating film to fill said second concaves, said coating film having potential to produce the H⁺ by a reaction relating to H₂O.
